(19) United States
(12) Patent Application Publication
(10) Pub. No.: US 2024/0413283 A1
(43) Pub. Date: Dec. 12, 2024

(54) HYBRID PANEL AND SPLICED PANEL

(71) Applicant: TCL CHINA STAR OPTOELECTRONICS TECHNOLOGY CO., LTD., Shenzhen, Guangdong (CN)

(72) Inventors: Jun ZHAO, Shenzhen, Guangdong (CN); Hongyuan XU, Shenzhen, Guangdong (CN); Meinan LI, Shenzhen, Guangdong (CN)

(21) Appl. No.: 17/596,678

(22) PCT Filed: Nov. 22, 2021
(86) PCT No.: PCT/CN2021/132084

§ 371 Date: Aug. 20, 2024

(30) Foreign Application Priority Data
Nov. 9, 2021 (CN) 202111319877.3

(51) Int. Cl. H01L 33/62; H01L 25/075

(52) U.S. Cl. CPC H01L 33/62; H01L 25/0753

(57) ABSTRACT

A hybrid panel and a spliced panel are disclosed. The hybrid panel includes a display panel and a light-emitting diode (LED) substrate, and the display panel includes a display region and a non-display region disposed around the display region. The LED substrate is formed on the display panel. The LED substrate is located in the non-display region.

### FIELD OF INVENTION

The present disclosure relates to the field of display technologies, and in particular, to a hybrid panel and a spliced panel.

### BACKGROUND OF INVENTION

During the research and practice of the prior art, it is found that, with the rapid development of the outdoor display market, large size and high resolution have become a development direction of outdoor display. Conventional liquid crystal display (LCD) panels have the advantages of low costs and high resolution. However, when LCD panels are spliced, there is a large pitch between the display regions, affecting the visual effect. The small-pitch manufacturing process for Mini LED panels and micro LED panels is still not mature, and has the problems of lower resolution than LCD panels and high costs. Therefore, how to reduce the gap between LCD splicing screens become a key breakthrough point that requires to be resolved urgently.

### SUMMARY OF THE INVENTION

### Technical Problem

The present disclosure provides a hybrid panel and a spliced panel. A light-emitting diode (LED) substrate may be disposed in a non-display region of a display panel, thereby increasing the display area of the hybrid panel, and reducing the pitch between two adjacent display regions in the spliced panel.

### Technical Solution

The present disclosure provides a hybrid panel, including:
a display panel including a display region and a non-display region disposed around the display region; and
an LED substrate disposed on the display panel and located in the non-display region.

In the hybrid panel of the present disclosure, the LED substrate is prepared in the non-display region of the display panel, to increase the display area of the entire hybrid panel, and the LED substrate is prepared on the display panel, so that the effect of thinning the LED substrate is achieved.

Optionally, in some embodiments of the present disclosure, the display panel includes a first surface located at a light emitting side of the display panel, a second surface located at a light incident side of the display panel, and a third surface connected between the first surface and the second surface;
the LED substrate is disposed on the first surface, the LED substrate includes a plurality of first driving wirings, the display panel includes a plurality of second driving wirings, the hybrid panel includes a first lead wire, a second lead wire, a plurality of first bonding pads, and a plurality of second bonding pads, the first lead wire and the second lead wire are disposed on the third surface, the first lead wire is connected to the first driving wirings, and the second lead wire is connected to the second driving wirings; and the first bonding pads are connected to the first lead wire, and the second bonding pads are connected to the second lead wire; and
the first bonding pads and the second bonding pads are disposed on the third surface or the second surface.

In the hybrid panel in the embodiments of the present disclosure, a bonding region of the display panel and a bonding region of the LED substrate are disposed on the second surface or the third surface. That is, in the hybrid panel in the present embodiment, a bezel is reduced in a manner of side surface bonding or back surface bonding.

Optionally, in some embodiments of the present disclosure, the first bonding pads and the second bonding pads are alternately arranged, so that the first driving wirings and the second driving wirings may be spaced to save space.

Optionally, in some embodiments of the present disclosure, the display panel includes a first substrate and a second substrate disposed opposite to each other and a filling layer disposed between the first substrate and the second substrate, and a side surface of the first substrate, a side surface of the filling layer, and a side surface of the second substrate are flush and form the third surface.

The flat third surface facilitates preparation of the first lead wire, the second lead wire, the first bonding pads, and the second bonding pads.

Optionally, in some embodiments of the present disclosure, the display panel includes a first substrate and a second substrate disposed opposite to each other, the second substrate is an array substrate, and the LED substrate includes a first driving wiring;
the first substrate includes a first base and an electrical connection structure, the electrical connection structure is located in the non-display region, the LED substrate is disposed on the first base, and the electrical connection structure is disposed on a surface of the first base away from the LED substrate;
the second substrate includes a second base, a connection pad, and a first bonding pad, the connection pad is disposed on a surface of the second base close to the first substrate, and the first bonding pad is disposed on a surface of the second base away from the first substrate; and
the first driving wiring is electrically connected to the electrical connection structure, the electrical connection structure is electrically connected to the connection pad, and the connection pad is electrically connected to the first bonding pad.

In the present embodiment, the electrical connection structure is prepared in the first substrate, and the connection pad is prepared in the second substrate. Compared with the above embodiments, the preparation process of the present embodiment is simpler, and the bezel width is further reduced.

Optionally, in some embodiments of the present disclosure, a first via hole is provided on the first base, the electrical connection structure includes a bump and a conductive film, the bump is disposed on a surface of the first base away from the LED substrate, the conductive film covers the bump, a part of the conductive film covering the bump is connected to the connection pad, and a part of the conductive film is connected to the first driving wiring through the first via hole.

In the present embodiment, the bump and the conductive film are prepared in the first substrate, so that the connection pad in the second substrate is connected.

Optionally, in some embodiments of the present disclosure, the first substrate further includes a common electrode, and the common electrode and the conductive film are disposed in a same layer in an insulated manner. That is, the common electrode and the conductive film are formed by using a same masking process, to reduce process steps.

Optionally, in some embodiments of the present disclosure, the second substrate further includes a second driving wiring and a second bonding pad, the second driving wiring is disposed on the surface of the second base close to the first substrate and is disposed spaced apart from the connection pad, and the second bonding pad is disposed on the surface of the second base away from the first substrate and is disposed spaced apart from the first bonding pad; and
a plurality of second via holes are provided on the second base, and the second driving wiring is connected to the second bonding pad through the second via holes, to achieve back surface bonding.

Optionally, in some embodiments of the present disclosure, the hybrid panel further includes at least one first flexible circuit board and at least one second flexible circuit board, the first flexible circuit board is connected to the first bonding pads, and the second flexible circuit board is connected to the second bonding pads, to achieve respective driving connection of the LED substrate and the display panel.

Optionally, in some embodiments of the present disclosure, the LED substrate includes a metal layer, an insulating layer, a black light-absorbing layer, and a plurality of LEDs disposed on the display panel, the metal layer includes the first driving wirings and a solder pad, the insulating layer covers the first driving wirings and exposes the solder pad, the LEDs are disposed on the solder pad, and the black light-absorbing layer is disposed on the insulating layer and is disposed between the LEDs.

The black light-absorbing layer covers the insulating layer and is disposed between the LEDs. In this way, on the one hand, contrast can be improved when the LED substrate displays an image. On the other hand, the light-emitting brightness of the LED substrate is reduced, thereby reducing the light-emitting brightness difference between the display panel and the LED substrate, and improving the overall display effect of the hybrid panel.

Correspondingly, the embodiments of the present disclosure further provide a spliced panel. The spliced panel includes at least two hybrid panels; the hybrid panels are spliced to form a gap; and each of the hybrid panels includes:
a display panel including a display region and a non-display region disposed around the display region; and
an LED substrate disposed on the display panel and located in the non-display region; wherein
the LED substrate is disposed at each of two sides of the gap.

Optionally, in some embodiments of the present disclosure, the display panel includes a first surface located at a light emitting side of the display panel, a second surface located at a light incident side of the display panel, and a third surface connected between the first surface and the second surface;
the LED substrate is disposed on the first surface, the LED substrate includes a plurality of first driving wirings, the display panel includes a plurality of second driving wirings, the hybrid panel includes a first lead wire, a second lead wire, a plurality of first bonding pads, and a plurality of second bonding pads, the first lead wire and the second lead wire are disposed on the third surface, the first lead wire is connected to the first driving wirings, and the second lead wire is connected to the second driving wirings; and the first bonding pads are connected to the first lead wire, and the second bonding pads are connected to the second lead wire; and
the first bonding pads and the second bonding pads are disposed on the third surface or the second surface.

In the hybrid panel in the embodiments of the present disclosure, a bonding region of the display panel and a bonding region of the LED substrate are disposed on the second surface or the third surface. That is, in the hybrid panel in the present embodiment, a bezel is reduced in a manner of side surface bonding or back surface bonding.

Optionally, in some embodiments of the present disclosure, the first bonding pads and the second bonding pads are alternately arranged, so that the first driving wirings and the second driving wirings may be spaced to save space.

Optionally, in some embodiments of the present disclosure, the display panel includes a first substrate and a second substrate disposed opposite to each other and a filling layer disposed between the first substrate and the second substrate, and a side surface of the first substrate, a side surface of the filling layer, and a side surface of the second substrate are flush and form the third surface.

The flat third surface facilitates preparation of the first lead wire, the second lead wire, the first bonding pads, and the second bonding pads.

Optionally, in some embodiments of the present disclosure, the display panel includes a first substrate and a second substrate disposed opposite to each other, the second substrate is an array substrate, and the LED substrate includes a first driving wiring;
the first substrate includes a first base and an electrical connection structure, the electrical connection structure is located in the non-display region, the LED substrate is disposed on the first base, and the electrical connection structure is disposed on a surface of the first base away from the LED substrate;
the second substrate includes a second base, a connection pad, and a first bonding pad, the connection pad is disposed on a surface of the second base close to the first substrate, and the first bonding pad is disposed on a surface of the second base away from the first substrate; and the first driving wiring is electrically connected to the electrical connection structure,
the electrical connection structure is electrically connected to the connection pad, and the connection pad is electrically connected to the first bonding pad.

In the present embodiment, the electrical connection structure is prepared in the first substrate, and the connection pad is prepared in the second substrate. Compared with the above embodiments, the preparation process of the present embodiment is simpler, and the bezel width is further reduced.

Optionally, in some embodiments of the present disclosure, a first via hole is provided on the first base, the electrical connection structure includes a bump and a conductive film, the bump is disposed on a surface of the first base away from the LED substrate, the conductive film covers the bump, a part of the conductive film covering the bump is connected to the connection pad, and a part of the conductive film is connected to the first driving wiring through the first via hole.

In the present embodiment, the bump and the conductive film are prepared in the first substrate, so that the connection pad in the second substrate is connected.

Optionally, in some embodiments of the present disclosure, the first substrate further includes a common electrode, and the common electrode and the conductive film are disposed in a same layer in an insulated manner. That is, the common electrode and the conductive film are formed by using a same masking process, to reduce process steps.

Optionally, in some embodiments of the present disclosure, the second substrate further includes a second driving wiring and a second bonding pad, the second driving wiring is disposed on the surface of the second base close to the first substrate and is disposed spaced apart from the connection pad, and the second bonding pad is disposed on the surface of the second base away from the first substrate and is disposed spaced apart from the first bonding pad; and
a plurality of second via holes are provided on the second base, and the second driving wiring is connected to the second bonding pad through the second via holes, to achieve back surface bonding.

Optionally, in some embodiments of the present disclosure, the hybrid panel further includes a first flexible circuit board and a second flexible circuit board, the first flexible circuit board is connected to the first bonding pad, and the second flexible circuit board is connected to the second bonding pad, to achieve respective driving connection of the LED substrate and the display panel.

Optionally, in some embodiments of the present disclosure, the LED substrate includes a metal layer, an insulating layer, a black light-absorbing layer, and a plurality of LEDs disposed on the display panel, the metal layer includes the first driving wiring and a solder pad, the insulating layer covers the first driving wiring and exposes the solder pad, the LEDs are disposed on the solder pad, and the black light-absorbing layer is disposed on the insulating layer and is disposed between the LEDs.

The black light-absorbing layer covers the insulating layer and is disposed between the LEDs. In this way, on the one hand, contrast can be improved when the LED substrate displays an image. On the other hand, the light-emitting brightness of the LED substrate is reduced, thereby reducing the light-emitting brightness difference between the display panel and the LED substrate, and improving the overall display effect of the hybrid panel.

### Beneficial Effects

The hybrid panel of the embodiments of the present disclosure includes the display panel and the LED substrate, and the display panel includes the display region and the non-display region disposed around the display region; and the LED substrate is formed on the display panel and located in the non-display region. In the hybrid panel of the present embodiment, the LED substrate is prepared in the non-display region of the display panel, to increase the display area of the entire hybrid panel, and the LED substrate is prepared on the display panel, so that the effect of thinning the LED substrate is achieved.

In addition, in the spliced panel of the present embodiment, two adjacent hybrid panels are spliced to form a gap, and one LED substrate is disposed at each of two sides of the gap, to reduce the pitch between display regions of the two hybrid panels, thereby improving the display effect.

### BRIEF DESCRIPTION OF DRAWINGS

To describe the technical solutions in the embodiments of the present disclosure more clearly, the following briefly introduces the accompanying drawings required for describing the embodiments. Apparently, the accompanying drawings in the following descriptions show only some embodiments of the present disclosure, and a person skilled in the art may still derive other accompanying drawings from these accompanying drawings without creative efforts.

FIG. 1 is a schematic diagram of a structure of a hybrid panel according to a first embodiment of the present disclosure.

FIG. 2 is a schematic side view of the hybrid panel according to the first embodiment of the present disclosure.

FIG. 3 is a schematic diagram of a structure of a hybrid panel according to a second embodiment of the present disclosure.

FIG. 4 is a schematic side view of the hybrid panel according to the second embodiment of the present disclosure.

FIG. 5 is a schematic diagram of a structure of a hybrid panel according to a third embodiment of the present disclosure.

FIG. 6 is a schematic diagram of a structure of a spliced panel according to an embodiment of the present disclosure.

### DETAILED DESCRIPTION OF PREFERRED EMBODIMENTS

The technical solutions in the embodiments of the present disclosure are clearly and completely described below with reference to the accompanying drawings in the embodiments of the present disclosure. Apparently, the described embodiments are merely some rather than all of the embodiments of the present disclosure. All other embodiments obtained by a person skilled in the art based on the embodiments of the present disclosure without creative efforts shall fall within the protection scope of the present disclosure. In addition, it should be understood that the specific implementations described herein are merely used for describing and illustrating the present disclosure rather than limiting the present disclosure. In the present disclosure, without the contrary explanation, the directional terms such as “above” and “below” generally refer to “above” and “below” in actual use or a working state of a device, and specifically refer to drawing directions of the corresponding accompanying drawings; and “inside” and “outside” are relative to the contour of the device.

The embodiments of the present disclosure provide a hybrid panel and a spliced panel, and detailed descriptions are provided below. The description sequence of the following embodiments is not intended to limit preference orders of the embodiments.

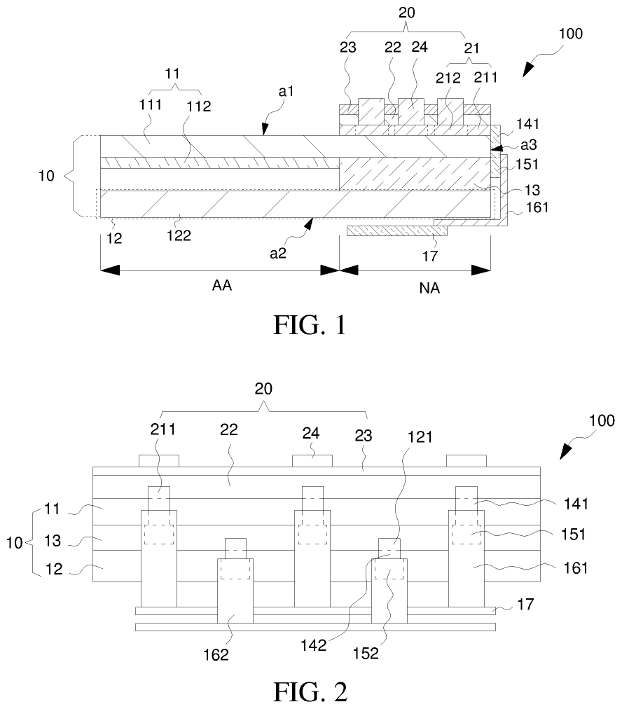

Referring to FIG. 1, a first embodiment of the present disclosure provides a hybrid panel 100, including a display panel 10 and a light-emitting diode (LED) substrate 20.

The display panel 10 includes a display region AA and a non-display region NA disposed around the display region AA.

The LED substrate 20 is formed on the display panel 10. The LED substrate 20 is located in the non-display region NA. Optionally, the LED substrate 20 may be disposed on at least one side of the non-display region NA.

In the hybrid panel 100 of the first embodiment, the LED substrate 20 is prepared in the non-display region NA of the display panel 10, to increase the display area of the entire hybrid panel 100, and the LED substrate 20 is prepared on the display panel 10, so that the effect of thinning the LED substrate 20 is achieved.

Optionally, the display panel 10 includes a first surface a1 located at a light emitting side of the display panel 10, a second surface a2 located at a light incident side of the display panel 10, and a third surface a3 connected between the first surface a1 and the second surface a2.

The LED substrate 20 is disposed on the first surface a1. The LED substrate 20 includes a metal layer 21, an insulating layer 22, a black light-absorbing layer 23, and a plurality of LEDs 24 disposed on the display panel 10. The metal layer 21 includes a plurality of first driving wirings 211 and a solder pad 212 connected to the first driving wirings 211. The insulating layer 22 covers the first driving wirings 211 and exposes the solder pad 212. The LEDs 24 are disposed on the solder pad 212. The black light-absorbing layer 23 is disposed on the insulating layer 22 and is disposed between the LEDs 24.

The black light-absorbing layer 23 covers the insulating layer 22 and is disposed between the LEDs 24. In this way, on the one hand, contrast can be improved when the LED substrate 20 displays an image. On the other hand, the light-emitting brightness of the LED substrate 20 is reduced, thereby reducing the light-emitting brightness difference between the display panel 10 and the LED substrate 20, and improving the overall display effect of the hybrid panel 100.

Optionally, the black light-absorbing layer 23 may be made of an inorganic metal material, such as chromium (Cr), molybdenum (Mo), or manganese (Mn), or a metal oxide material, such as CrOₓ, MoOₓ, or MnO₂, or may be a mixed film formed by a metal and a metal oxide; or may be made of an organic black resinous material, such as black polystyrene or black photoresist.

Optionally, the display panel 10 includes a first substrate 11 and a second substrate 12 disposed opposite to each other and a filling layer 13 disposed between the first substrate 11 and the second substrate 12.

Optionally, referring to FIG. 1 and FIG. 2, the first substrate 11 is located at the light emitting side of the display panel 10. The second substrate 12 includes a plurality of second driving wirings 121.

The hybrid panel 100 includes a first lead wire 141, a second lead wire 142, a plurality of first bonding pads 151, and a plurality of second bonding pads 152. The first lead wire 141 and the second lead wire 142 are disposed on the third surface a3. The first lead wire 141 is connected to the first driving wirings 211. The second lead wire 142 is connected to the second driving wirings 121. The first bonding pads 151 are connected to the first lead wire 141. The second bonding pads 152 are connected to the second lead wire 142. The first bonding pads 151 and the second bonding pads 152 are disposed on the third surface a3.

Optionally, the hybrid panel 100 further includes a plurality of first flexible circuit boards 161 and a plurality of second flexible circuit boards 162. Each of the first flexible circuit boards 161 is connected to one of the first bonding pads 151. Each of the second flexible circuit boards 162 is connected to one of the second bonding pads 152.

In the hybrid panel 100 of the first embodiment, a bonding region of the display panel 10 and a bonding region of the LED substrate 20 are disposed on the third surface a3. That is, in the hybrid panel 100 of the first embodiment, a bezel is reduced in a manner of side surface bonding.

Optionally, the first lead wire 141 and the second lead wire 142 may be made of silver or another metal material.

Optionally, the first bonding pads 151 and the second bonding pads 152 are alternately arranged, so that the first driving wirings 211 and the second driving wirings 121 may be spaced to save space.

Optionally, a side surface of the first substrate 11, a side surface of the filling layer 13, and a side surface of the second substrate 12 are flush and form the third surface a3. The flat third surface a3 facilitates preparation of the first lead wire 141, the second lead wire 142, the first bonding pads 151, and the second bonding pads 152.

In some embodiments, the first driving wiring 211 is connected between adjacent solder pads 212, wherein the first lead wire 141 is directly connected to an outermost solder pad 212, to save partial first driving wiring 211, thereby reducing the bezel width of the LED substrate 20, and further reducing the pitch between LEDs 24 located at two sides of a gap between two LED substrates 20 after two display panels 10 are spliced.

Optionally, the display panel 10 may be an electroluminescent panel, such as an organic light-emitting diode (OLED) panel or a quantum dot light-emitting diode (QLED) panel, or a liquid crystal display (LCD) panel. When the display panel 10 is an electroluminescent panel, the first substrate 11 may be a glass substrate, and the second substrate 12 is an organic/inorganic LED substrate. When the display panel 10 is an LCD panel, the first substrate 11 may be one of a color filter substrate and an array substrate, and the second substrate 12 may be an other of the color filter substrate and the array substrate.

The hybrid panel 100 of the first embodiment is described by using an example in which the display panel 10 is an LCD panel. The present disclosure is not limited thereto. Optionally, the first substrate 11 is a color filter substrate, and the second substrate 12 is an array substrate.

Optionally, the filling layer 13 may be a sealant, or another filling material used for filling a gap between the first substrate 11 and the second substrate 12.

Optionally, a resolution of the display panel 10 is same as a resolution of the LED substrate 20, to improve the display efficiency.

Optionally, the first substrate 11 further includes a first base 111 and a color filter layer 112 disposed on the first base 111. A material of the color filter layer 112 includes a plurality of quantum dots, so that the color gamut of the display panel 10 is same as the color gamut of the LED substrate 20.

The second substrate 12 further includes a second base 122. The second driving wiring 121 is disposed on a surface of the second base 122 close to the first substrate 11.

Optionally, the hybrid panel 100 may further include at least one driving plate 17. One driving plate 17 is connected to the first flexible circuit boards 161. Another driving plate 17 is connected to the second flexible circuit boards 162.

In some embodiments, one driving plate 17 may be connected to the first flexible circuit boards 161 and the second flexible circuit boards 162 simultaneously.

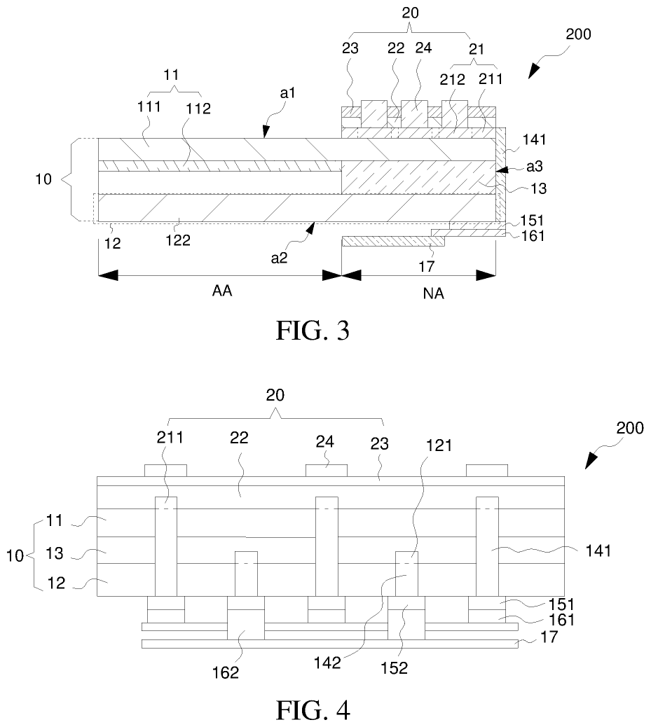

Referring to FIG. 3 and FIG. 4, a difference between a hybrid panel 200 of a second embodiment and the hybrid panel 100 of the first embodiment lies in that, in the hybrid panel 200 of the second embodiment, a flexible circuit board is bound in a manner of back surface bonding. That is, the first bonding pads 151 and the second bonding pads 152 are disposed on the second surface a2.

Compared with the manner of side surface bonding, the manner of back surface bonding further reduces the bezel width.

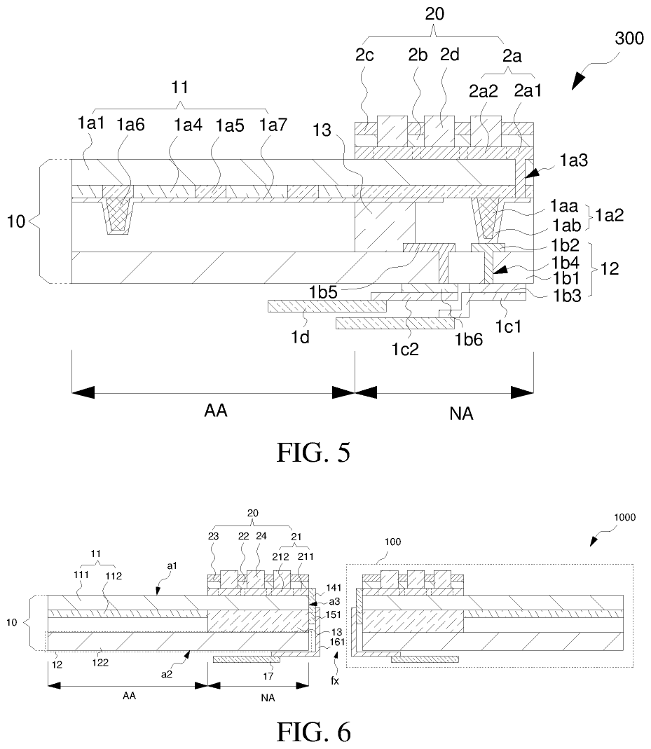

Referring to FIG. 5, a hybrid panel 300 of a third embodiment includes a display panel 10 and an LED substrate 20.

The display panel 10 includes a display region AA and a non-display region NA disposed around the display region AA. The LED substrate 20 is formed on the display panel 10. The LED substrate 20 is located in the non-display region NA.

In the hybrid panel 100 of the first embodiment, the LED substrate 20 is prepared in the non-display region NA of the display panel 10, to increase the display area of the entire hybrid panel 100, and the LED substrate 20 is prepared on the display panel 10, so that the effect of thinning the LED substrate 20 is achieved.

Optionally, the display panel 10 includes a first substrate 11 and a second substrate 12 disposed opposite to each other. The second substrate 12 is an array substrate. The display panel 10 further includes a sealant 13 disposed between the first substrate 11 and the second substrate 12.

Optionally, the LED substrate 20 includes a metal layer 2a, an insulating layer 2b, a black light-absorbing layer 2c, and a plurality of LEDs 2d disposed on the first substrate 11. The metal layer 2a includes a first driving wiring 2a1 and a solder pad 2a2 connected to the first driving wiring 2a1. The insulating layer 2b covers the first driving wiring 2a1 and exposes the solder pad 2a2. The LEDs 2d are disposed on the solder pad 2a2. The black light-absorbing layer 2c is disposed on the insulating layer 2b and is disposed between the LEDs 2d.

The black light-absorbing layer 2c covers the insulating layer 2b and is disposed between the LEDs 2d. In this way, on the one hand, contrast can be improved when the LED substrate 20 displays an image. On the other hand, the light-emitting brightness of the LED substrate 20 can be reduced, thereby reducing the light-emitting brightness difference between the display panel 10 and the LED substrate 20, and improving the overall display effect of the hybrid panel 300.

Optionally, the black light-absorbing layer 2c may be made of an inorganic metal material, such as chromium (Cr), molybdenum (Mo), or manganese (Mn), or a metal oxide material, such as CrOₓ, MoOₓ, or MnO₂, or may be a mixed film formed by a metal and a metal oxide; or may be made of an organic black resinous material, such as black polystyrene or black photoresist.

Optionally, the first substrate 11 includes a first base 1a1 and an electrical connection structure 1a2. The electrical connection structure 1a2 is located in the non-display region NA. The LED substrate 20 is disposed on the first base 1a1. The electrical connection structure 1a2 is disposed on a surface of the first base 1a1 away from the LED substrate 20.

The second substrate 12 includes a second base 1b1, a connection pad 1b2, and a first bonding pad 1b3. The connection pad 1b2 is disposed on a surface of the second base 1b1 close to the first substrate 11. The first bonding pad 1b3 is disposed on a surface of the second base 1b1 away from the first substrate 11.

The first driving wiring 2a1 is electrically connected to the electrical connection structure 1a2. The electrical connection structure 1a2 is electrically connected to the connection pad 1b2. The connection pad 1b2 is electrically connected to the first bonding pad 1b3.

Optionally, a first via hole 1a3 is provided on the first base 1a1. The first driving wiring 2a1 is electrically connected to the electrical connection structure 1a2 through the first via hole 1a3. A plurality of second via holes 1b4 are provided on the second base 1b1, and the connection pad 1b2 is connected to the first bonding pad 1b3 through one of the second via holes 1b4.

In the hybrid panel 300 of the third embodiment, the first via hole 1a3 and the electrical connection structure 1a2 are disposed on the first substrate 11, and the connection pad 1b2 are disposed on and the second via holes 1b4 are provided on the second substrate 12, so that an electrical connection channel of the first driving wiring 2a1 is guided to a back surface of the second substrate 12 to implement back surface bonding. In the hybrid panel 300 of the third embodiment, the electrical connection structure 1a2 is prepared in the first substrate 11, and the connection pad 1b2 is prepared in the second substrate 12. Compared with the first embodiment and the second embodiment, the preparation process of the third embodiment is simpler, and the bezel width is further reduced.

Optionally, the electrical connection structure 1a2 includes a bump 1aa and a conductive film lab. The bump 1aa is disposed on a surface of the first base 1a1 away from the LED substrate 20. The conductive film lab covers the bump 1aa. A part of the conductive film lab covering the bump 1aa is connected to the connection pad 1b2. A part of the conductive film lab is connected to the first driving wiring 2a1 through the first via hole 1a3.

Optionally, the first substrate 11 may further include a color filter layer 1a4, a plurality of black matrices 1a5, and at least one spacer supports 1a6. The spacer supports 1a6 is disposed on one of the black matrices 1a5. The spacer support 1a6 and the bump 1aa are formed by using a same masking process.

Optionally, a material of the color filter layer 1a4 includes a plurality of quantum dots, so that the color gamut of the display panel 10 is same as the color gamut of the LED substrate 20.

Optionally, the black matrices 1a5 are also disposed in the non-display region NA.

Optionally, the first substrate 11 further includes a common electrode 1a7. The common electrode 1a7 covers the color filter layer 1a4 and the spacer support 1a6. The common electrode 1a7 and the conductive film lab are disposed in a same layer in an insulated manner. That is, the common electrode 1a7 and the conductive film lab are formed by using a same masking process.

Optionally, the second substrate 12 further includes a second driving wiring 1b5 and a second bonding pad 1b6. The second driving wiring 1b5 is disposed on the surface of the second base 1b1 close to the first substrate 11 and is disposed spaced apart from the connection pad 1b2. The second bonding pad 1b6 is disposed on the surface of the second base 1b1 away from the first substrate 11 and is disposed spaced apart from the first bonding pad 1b3.

The second driving wiring 1b5 is connected to the second bonding pad 1b6 through part of the second via holes 1b4.

Optionally, the hybrid panel 300 further includes a first flexible circuit board 1cl and a second flexible circuit board 1c2. The first flexible circuit board 1cl is connected to the first bonding pad 1b3. The second flexible circuit board 1c2 is connected to the second bonding pad 1b6.

Optionally, a resolution of the display panel 10 is same as a resolution of the LED substrate 20, to improve the display efficiency.

Optionally, the hybrid panel 300 may further include at least one driving plate 1d. One driving plate 1d is connected to the first flexible circuit board 1c1. Another driving plate 1d is connected to the second flexible circuit board 1c2.

In some embodiments, one driving plate 1d may be separately connected to the first flexible circuit board 1cl and the second flexible circuit board 1c2.

Optionally, the length of the first substrate 11 is equal to the length of the second substrate 12, so that surrounding side surfaces of the first substrate 11 are flush with surrounding side surfaces of the second substrate 12. Compared with an LCD panel in the prior art, in the hybrid panel 300 of the third embodiment, the length of the first substrate 11 is increased so that the electrical connection structure 1a2 is disposed. The second bonding pad 1b6 is transferred to a back surface of the second substrate 12, and the connection pad 1b2 is disposed at a position at which the second bonding pad 1b6 is originally disposed on the second substrate 12, thereby implementing the back surface bonding without increasing the non-display region NA of the display panel 10, and further reducing the bezel width.

Referring to FIG. 6, correspondingly, the embodiments of the present disclosure further provide a spliced panel 1000. The spliced panel 1000 includes at least two hybrid panels (100/200/300) as claimed in any one of the above embodiments. The hybrid panels (100/200/300) are spliced to form a gap fx. One LED substrate 20 is disposed at each of two sides of the gap fx.

The structures of the hybrid panels (100/200/300) of the above embodiments are described in the foregoing, so the details will not be described herein again.

Descriptions are made by using an example in which the spliced panel 1000 of the present embodiment includes the hybrid panel 100 of the first embodiment. This is not limited thereto.

A plurality of first flexible circuit boards 161 and a plurality of second flexible circuit boards 162 are located in the gap fx.

The spliced panel 1000 of the embodiments of the present disclosure includes at least two hybrid panels 100, the hybrid panel 100 includes a display panel 10 and an LED substrate 20, and the display panel 10 includes a display region AA and a non-display region NA disposed around the display region AA; The LED substrate 20 is formed on the display panel 10. The LED substrate 20 is located in the non-display region NA. In the present embodiment, the LED substrate 20 is prepared in the non-display region NA of the display panel 10, to increase the display area of the entire hybrid panel 100, and the LED substrate 20 is prepared on the display panel 10, so that the effect of thinning the LED substrate 20 is achieved.

In addition, in the present embodiment, the LED substrate 20 is disposed at each of two sides of the gap fx, to reduce the pitch between the two hybrid panels 100 in an entire display region, thereby improving the display effect.

The hybrid panel and the spliced panel provided in the present disclosure are described in detail above. The principle and implementations of the present disclosure are described herein by using specific examples. The descriptions of the above embodiments are merely used for helping understand the method and core ideas of the present disclosure. Meanwhile, a person of ordinary skill in the art may make modifications to the specific implementations and application scopes according to the ideas of the present disclosure. In conclusion, the content of the specification should not be construed as a limitation to the present disclosure.

1. A hybrid panel, comprising:
a display panel comprising a display region and a non-display region disposed around the display region; and
a light-emitting diode (LED) substrate disposed on the display panel and located in the non-display region.

2. The hybrid panel as claimed in claim 1, wherein the display panel comprises a first surface located at a light emitting side of the display panel, a second surface located at a light incident side of the display panel, and a third surface connected between the first surface and the second surface;
the LED substrate is disposed on the first surface, the LED substrate comprises a plurality of first driving wirings, the display panel comprises a plurality of second driving wirings, the hybrid panel comprises a first lead wire, a second lead wire, a plurality of first bonding pads, and a plurality of second bonding pads, the first lead wire and the second lead wire are disposed on the third surface, the first lead wire is connected to the first driving wirings, and the second lead wire is connected to the second driving wirings; and the first bonding pads are connected to the first lead wire, and the second bonding pads are connected to the second lead wire; and
the first bonding pads and the second bonding pads are disposed on the third surface or the second surface.

3. The hybrid panel as claimed in claim 2, wherein the first bonding pads and the second bonding pads are alternately arranged.

4. The hybrid panel as claimed in claim 2, wherein the display panel comprises a first substrate and a second substrate disposed opposite to each other and a filling layer disposed between the first substrate and the second substrate, and a side surface of the first substrate, a side surface of the filling layer, and a side surface of the second substrate are flush and form the third surface.

5. The hybrid panel as claimed in claim 1, wherein the display panel comprises a first substrate and a second substrate disposed opposite to each other, the second substrate is an array substrate, and the LED substrate comprises a first driving wiring;
the first substrate comprises a first base and an electrical connection structure, the electrical connection structure is located in the non-display region, the LED substrate is disposed on the first base, and the electrical connection structure is disposed on a surface of the first base away from the LED substrate;
the second substrate comprises a second base, a connection pad, and a first bonding pad, the connection pad is disposed on a surface of the second base close to the first substrate, and the first bonding pad is disposed on a surface of the second base away from the first substrate; and
the first driving wiring is electrically connected to the electrical connection structure, the electrical connection structure is electrically connected to the connection pad, and the connection pad is electrically connected to the first bonding pad.

6. The hybrid panel as claimed in claim 5, wherein a first via hole is provided on the first base, the electrical connection structure comprises a bump and a conductive film, the bump is disposed on a surface of the first base away from the LED substrate, the conductive film covers the bump, a part of the conductive film covering the bump is connected to the connection pad, and a part of the conductive film is connected to the first driving wiring through the first via hole.

7. The hybrid panel as claimed in claim 6, wherein the first substrate further comprises a common electrode, and the common electrode and the conductive film are disposed in a same layer in an insulated manner.

8. The hybrid panel as claimed in claim 5, wherein the second substrate further comprises a second driving wiring and a second bonding pad, the second driving wiring is disposed on the surface of the second base close to the first substrate and is disposed spaced apart from the connection pad, and the second bonding pad is disposed on the surface of the second base away from the first substrate and is disposed spaced apart from the first bonding pad; and
a plurality of second via holes are provided on the second base, and the second driving wiring is connected to the second bonding pad through the second via holes.

9. The hybrid panel as claimed in claim 2, wherein the hybrid panel further comprises at least one first flexible circuit board and at least one second flexible circuit board, the first flexible circuit board is connected to the first bonding pads, and the second flexible circuit board is connected to the second bonding pads.

10. The hybrid panel as claimed in claim 2, wherein the LED substrate comprises a metal layer, an insulating layer, a black light-absorbing layer, and a plurality of LEDs disposed on the display panel, the metal layer comprises the first driving wirings and a solder pad, the insulating layer covers the first driving wirings and exposes the solder pad, the LEDs are disposed on the solder pad, and the black light-absorbing layer is disposed on the insulating layer and is disposed between the LEDs.

11. A spliced panel, comprising at least two hybrid panels, wherein the hybrid panels are spliced to form a gap, and each of the hybrid panels comprises:
a display panel comprising a display region and a non-display region disposed around the display region; and
a light-emitting diode (LED) substrate disposed on the display panel and located in the non-display region; wherein
the LED substrate is disposed at each of two sides of the gap.

12. The spliced panel as claimed in claim 11, wherein the display panel comprises a first surface located at a light emitting side of the display panel, a second surface located at a light incident side of the display panel, and a third surface connected between the first surface and the second surface;
the LED substrate is disposed on the first surface, the LED substrate comprises a plurality of first driving wirings, the display panel comprises a plurality of second driving wirings, the hybrid panel comprises a first lead wire, a second lead wire, a plurality of first bonding pads, and a plurality of second bonding pads, the first lead wire and the second lead wire are disposed on the third surface, the first lead wire is connected to the first driving wirings, and the second lead wire is connected to the second driving wirings; and the first bonding pads are connected to the first lead wire, and the second bonding pads are connected to the second lead wire; and
the first bonding pads and the second bonding pads are disposed on the third surface or the second surface.

13. The spliced panel as claimed in claim 12, wherein the first bonding pads and the second bonding pads are alternately arranged.

14. The spliced panel as claimed in claim 12, wherein the display panel comprises a first substrate and a second substrate disposed opposite to each other and a filling layer disposed between the first substrate and the second substrate, and a side surface of the first substrate, a side surface of the filling layer, and a side surface of the second substrate are flush and form the third surface.

15. The spliced panel as claimed in claim 11, wherein the display panel comprises a first substrate and a second substrate disposed opposite to each other, the second substrate is an array substrate, and the LED substrate comprises a first driving wiring;
the first substrate comprises a first base and an electrical connection structure, the electrical connection structure is located in the non-display region, the LED substrate is disposed on the first base, and the electrical connection structure is disposed on a surface of the first base away from the LED substrate;
the second substrate comprises a second base, a connection pad, and a first bonding pad, the connection pad is disposed on a surface of the second base close to the first substrate, and the first bonding pad is disposed on a surface of the second base away from the first substrate; and
the first driving wiring is electrically connected to the electrical connection structure, the electrical connection structure is electrically connected to the connection pad, and the connection pad is electrically connected to the first bonding pad.

16. The spliced panel as claimed in claim 15, wherein a first via hole is provided on the first base, the electrical connection structure comprises a bump and a conductive film, the bump is disposed on a surface of the first base away from the LED substrate, the conductive film covers the bump, a part of the conductive film covering the bump is connected to the connection pad, and a part of the conductive film is connected to the first driving wiring through the first via hole.

17. The spliced panel as claimed in claim 16, wherein the first substrate further comprises a common electrode, and the common electrode and the conductive film are disposed in a same layer in an insulated manner.

18. The spliced panel as claimed in claim 15, wherein the second substrate further comprises a second driving wiring and a second bonding pad, the second driving wiring is disposed on the surface of the second base close to the first substrate and is disposed spaced apart from the connection pad, and the second bonding pad is disposed on the surface of the second base away from the first substrate and is disposed spaced apart from the first bonding pad; and
a plurality of second via holes are provided on the second base, and the second driving wiring is connected to the second bonding pad through the second via holes.

19. The spliced panel as claimed in claim 18, wherein the hybrid panel further comprises a first flexible circuit board and a second flexible circuit board, the first flexible circuit board is connected to the first bonding pad, and the second flexible circuit board is connected to the second bonding pad.

20. The spliced panel as claimed in claim 15, wherein the LED substrate comprises a metal layer, an insulating layer, a black light-absorbing layer, and a plurality of LEDs disposed on the display panel, the metal layer comprises the first driving wiring and a solder pad, the insulating layer covers the first driving wiring and exposes the solder pad, the LEDs are disposed on the solder pad, and the black light-absorbing layer is disposed on the insulating layer and is disposed between the LEDs.
